(19) United States
(12) Patent Application Publication
(10) Pub. No.: US 2014/0113420 A1
(43) Pub. Date: Apr. 24, 2014

(54) METHODS OF AVOIDING SHADOWING WHEN FORMING SOURCE/DRAIN IMPLANT REGIONS ON 3D SEMICONDUCTOR DEVICES

(71) Applicant: GLOBALFOUNDRIES INC., Grand Cayman (KY)

(72) Inventors: Vidmantas Sargunas, Clifton Park, NY (US); Yayi Wei, Altamont, NY (US); Jeong Soo Kim, Clifton Park, NY (US); Seung Y. Kim, Andover, MA (US)

(73) Assignee: GLOBALFOUNDRIES INC., Grand Cayman (KY)

(21) Appl. No.: 13/658,928

(22) Filed: Oct. 24, 2012

(51) Int. Cl. H01L 21/8238

(52) U.S. Cl. 438/231; 257/E21.632

(57) ABSTRACT

One illustrative method disclosed herein includes forming a patterned photoresist implant mask that has an opening that is defined, at least partially, by a plurality of non-vertical sidewalls, wherein the implant mask covers one of an N-type FinFET or P-type FinFET device, while the other of the N-type FinFET or P-type FinFET device is exposed by the opening in the patterned photoresist implant mask, and performing at least one source/drain implant process through the opening in the patterned photoresist implant mask to form a doped source/drain implant region in at least one fin of the FinFET device exposed by the opening in the patterned photoresist implant mask.

### BACKGROUND OF THE INVENTION

1. Field of the Invention

Generally, the present disclosure relates to the manufacture of sophisticated semiconductor devices, and, more specifically, to various methods of avoiding shadowing when forming source/drain implant regions on three-dimensional semiconductor devices, such as FinFET devices.

2. Description of the Related Art

The fabrication of advanced integrated circuits, such as CPU's, storage devices, ASIC's (application specific integrated circuits) and the like, requires the formation of a large number of circuit elements in a given chip area according to a specified circuit layout, wherein so-called metal oxide field effect transistors (MOSFETs or FETs) represent one important type of circuit element that substantially determines performance of the integrated circuits. A FET is a device that typically includes a source region, a drain region, a channel region that is positioned between the source region and the drain region, and a gate electrode positioned above the channel region. Current flow through the FET is controlled by controlling the voltage applied to the gate electrode. If a voltage that is less than the threshold voltage of the device is applied to the gate electrode, then there is no current flow through the device (ignoring undesirable leakage currents, which are relatively small). However, when a voltage that is equal to or greater than the threshold voltage of the device is applied to the gate electrode, the channel region becomes conductive, and electrical current is permitted to flow between the source region and the drain region through the conductive channel region.

To improve the operating speed of FETs, and to increase the density of FETs on an integrated circuit device, device designers have greatly reduced the physical size of FETs over the years. More specifically, the channel length of FETs has been significantly decreased, which has resulted in improving the switching speed of FETs. However, decreasing the channel length of a FET also decreases the distance between the source region and the drain region. In some cases, this decrease in the separation between the source and the drain makes it difficult to efficiently inhibit the electrical potential of the channel from being adversely affected by the electrical potential of the drain. This is sometimes referred to as a so-called short channel effect, wherein the characteristic of the FET as an active switch is degraded.

In contrast to a planar FET, which has a planar structure, there are so-called 3D devices, such as illustrative FinFET devices, which is a three-dimensional structure. FIG. 1A is a perspective view of an illustrative prior art FinFET semiconductor device 10 at an early stage of manufacturing that is formed above a semiconducting substrate 12. The illustrative device 10 includes a plurality of fins 14 that are defined in the substrate 12, a gate electrode 13, a gate insulation layer 14, sidewall spacers 17 and a gate cap layer 15. In a FinFET device, the gate structure (gate insulation layer 14 and gate electrode 13) encloses both of the sides and the upper surface of the fins 14 to form a tri-gate structure. This configuration results in a channel having a three-dimensional structure instead of a planar structure. In some cases, an insulating cap layer (not shown), e.g., silicon nitride, is positioned at the top of the fins 14 and the FinFET device only has a dual-gate structure. Unlike a planar FET, in a FinFET device, a channel is formed perpendicular to a surface of the semiconducting substrate so as to reduce the depletion width under the channel and thereby reduce so-called short channel effects. Also, in a FinFET, the junction capacitance at the drain region of the device is greatly reduced, which tends to reduce at least some short channel effects.

The basic structure of a field effect transistor is typically formed by forming various layers of material and thereafter patterning those layers of material using known photolithography and etching processes. Various doped regions, e.g., source regions, drain regions, halo regions, etc., are typically formed by performing one or more ion implantation processes through a patterned mask layer using an appropriate dopant material, e.g., an N-type dopant or a P-type dopant, to implant the desired dopant material into the substrate 12. The particular dopant selected depends on the specific implant region being formed and the type of device under construction, i.e., an NFET transistor or a PFET transistor. During the fabrication of complex integrated circuits, millions of transistors, e.g., NFET transistors and/or PFET transistors, are formed on a substrate by performing a number of process operations.

Device designers are under constant pressure to increase the operating speed and electrical performance of transistors and integrated circuit products that employ such transistors. Device designers are also under constant pressure to increase the packing density of transistors in a given substrate area or plot space so that the finished integrated circuit product will be reduced in size. Increasing the packing density necessarily involves placing individual transistors (or groups of transistors) of one type, e.g., N-type devices, very close to individual transistors (or groups of transistors) of the opposite type, e.g., P-type devices.

FIGS. 1B-1C are, respectively, a cross-sectional view and a plan view of one illustrative embodiment of an integrated circuit product comprised of an illustrative N-FinFET device 10N positioned between two P-FinFET devices 10P1, 10P2. The integrated circuit product is depicted at the point where trenches 16 have been formed in the substrate 12 to thereby define the fins 14. Local isolation regions 20 and device isolation regions 22 have been formed using traditional manufacturing techniques well known to those skilled in the art. The device isolation regions 22 separate the N-FinFET device 10N from the two P-FinFET devices 10P1, 10P2. In the example depicted in FIG. 1B, the N-FinFET device 10N and the P-FinFET device 10P1 are each comprised of three illustrative fins 14, while the P-FinFET device 10P2 is comprised of two fins 14. Of course, the number of fins 14 on the devices 10N, 10P1 and 10P2 may vary depending upon the particular application. In modern semiconductor manufacturing, the space 25 between adjacent devices (of the opposite type) may be as small as about 60 nm, and the drive is to reduce this spacing dimension even further so as to increase packing densities.

At the point of fabrication depicted in FIGS. 1B-1C, a patterned photoresist implant mask 24 has been formed above the substrate 12 in order to form source/drain regions (not shown) on the N-FinFET device 10N. The patterned photoresist implant mask 24 covers the two P-FinFET devices 10P1, 10P2 and exposes the N-FinFET device 10N for further processing. The patterned photoresist implant mask 24 may be formed using traditional photolithography equipment and techniques, and it may be made of either a positive or negative photoresist material. The thickness or height 24T of the patterned photoresist implant mask 24 may vary depending upon the particular application and a variety of factors, such as the implant energy to be used during the source/drain implant process(es). For example, the thickness or height 24T of the patterned photoresist implant mask 24 may range from about 100 nm to 0.5 μm or greater.

For ease of reference, the fins 14 in the N-FinFET device 10N have been labeled 14-1, 14-2 and 14-3. A representative ion implant process 26 is performed on the device for purposes of forming source/drain regions (not shown) in the fins 14 of the N-FinFET device 10N. The implant process 26 is representative in that the source/drain regions may be formed by performing one or more implant processes, e.g., by performing a so-called extension implant process followed by performing a so-called source/drain implant process. Importantly, the opening 24A in the patterned photoresist implant mask 24 has substantially vertically oriented sidewalls or edges, two of which (edges 24E1, 24E2) are depicted, that are oriented approximately normal to the surface of the substrate 12.

One problem with using such a patterned photoresist implant mask 24 is that, due to its thickness 24T, it tends to “shadow” the fins 14 when any angled implant process is performed on the fins 14. This shadowing effect by the vertical edge 24E1, depicted by the dashed line 28 in FIG. 1B, will block any implant into the sidewall 14S1 of the fin 14-1 for implant processes that are tilted (relative to vertical) more than the angle 28A. As noted earlier, in forming source/drain regions in the fins 14, it is desirable that the entire sidewall 14S1 of the fin 14 be implanted with the appropriate dopant material. Thus, the angled implant process 26 is performed at an angle 26A that may range from about 6-8 degrees in an effort to insure that the entire vertical height of the sidewall 14S1 is implanted with dopant material, as reflected by the dashed line 26B. Unfortunately, performing the implant process 26 at such a shallow implant angle 26A requires that the dopant dose used during the implant process 26 be relatively high. As a result, the ions used in the implant process 26 may damage the fins 14 via sputtering. Of course, as will be appreciated by those skilled in the art, the ion implant processes that are performed to form the source/drain regions for the N-FinFET device 10N are typically performed in multiple steps to avoid the shadowing effect of adjacent fins 14. For example, after the depicted implant process 26 is performed to form an implant region in the side 14S1 (and other corresponding sides of the fins 14-2 and 14-3), the device will be rotated 180°, another angled implant process 30 will be performed to form implant regions in the side 14S2 of the fin 14-3 (and other corresponding sides of the fins 14-1 and 14-2), wherein the edge 24E2 of the patterned photoresist implant mask 24 causes shadowing of the fins 14. One solution to the problems associated with the above-described patterned photoresist implant mask 24 would be to increase the spacing 25 until such time as the patterned photoresist implant mask 24 no longer shadows the fins 14 during the source/drain implant processes. However, such a solution would undesirably reduce packing densities. Another possible solution would be to form the ion implant mask from a traditional layer of material, like silicon nitride, i.e., form a patterned hard mask as opposed to a patterned photoresist mask. However, the formation and ultimate removal of such a patterned hard mask would be more expensive, and perhaps more difficult or time consuming, as compared to the formation and removal of a patterned photoresist mask.

The present disclosure is directed to various methods of avoiding shadowing when forming source/drain implant regions on three-dimensional semiconductor devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods of avoiding shadowing when forming source/drain implant regions on three-dimensional semiconductor devices, such as FinFET devices. One illustrative method disclosed herein includes forming a patterned photoresist implant mask that has an opening that is defined, at least partially, by a plurality of non-vertical sidewalls, wherein the implant mask covers one of an N-type FinFET or P-type FinFET device, while the other of the N-type FinFET or P-type FinFET device is exposed by the opening in the patterned photoresist implant mask, and performing at least one source/drain implant process through the opening in the patterned photoresist implant mask to form a doped source/drain implant region in at least one fin of the FinFET device exposed by the opening in the patterned photoresist implant mask.

Another illustrative method disclosed herein includes selecting a photoresist material that has a contrast curve that is adapted to, after exposure and development, produce a patterned photoresist implant mask having an opening comprised of a plurality of sloped sidewalls that are formed at an angle, with respect to a vertical, within the range of about 30-60°, forming a layer of the selected photoresist material above a device, performing at least exposure and development processes on the selected layer of photoresist material to thereby form the patterned photoresist implant mask with the plurality of sloped sidewalls, wherein the patterned photoresist implant mask covers one of an N-type FinFET or a P-type FinFET device, while the other of the N-type FinFET or P-type FinFET device is exposed by the opening in the patterned photoresist implant mask, and performing at least one source/drain implant process through the opening in the patterned photoresist implant mask to form a doped source/drain implant region in the at least one fin of the other of the N-type FinFET or P-type FinFET device exposed by the opening in the patterned photoresist implant mask.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1C depict one illustrative prior art technique and implant mask used in forming source/drain regions on FinFET devices; and

FIGS. 2A-2G depict various novel methods disclosed herein for forming a making layer in an effort to avoid or reduce shadowing when forming source/drain implant regions on three-dimensional semiconductor devices, such as FinFET devices.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure is directed to various methods of avoiding shadowing when forming source/drain implant regions on three-dimensional semiconductor devices, such as FinFET devices. As will be readily apparent to those skilled in the art upon a complete reading of the present application, the presently disclosed methods and devices may be employed when manufacturing NFET or PFET devices and when manufacturing a variety of different devices, including, but not limited to, logic devices, memory devices, ASICs, etc. With reference to the attached drawings, various illustrative embodiments of the methods and devices disclosed herein will now be described in more detail.

As used herein and in the attached claims, when it is stated that a “source/drain implant process” is performed or that a “source/drain implant region” is formed in the device, it should be understood to cover any and all aspects of various implant processes that may be performed to form doped source/drain regions in a transistor device. Moreover, the above phrases should be understood to cover the performance of one or more ion implant processes and the formation of one or more implant regions, respectively.

One typical multi-step ion implantation sequence for forming source/drain regions for a transistor device will now be generally described. After the formation of a gate structure for the transistor, an initial, so-called extension, ion implantation process is typically performed to form so-called extension implant regions in the substrate adjacent the gate structure. In some cases, a relatively small offset spacer may be formed adjacent the gate structure prior to performing the extension implant process. After the extension implant process is performed, a sidewall spacer is typically formed proximate the gate structure. Thereafter, a second, so-called source/drain ion implantation process, is performed on the transistor to form so-called highly doped source/drain implant regions in the substrate. The source/drain ion implantation process performed to form the highly doped source/drain implant regions is typically performed using a higher dopant dose. A heating or anneal process is then performed to form the final source/drain regions for the transistor. This heating process repairs the damage to the lattice structure of the substrate material as a result of the implantation processes and it activates the implanted dopant materials, i.e., the implanted dopant materials are incorporated into the silicon lattice. Of course, the type of dopants implanted, either N-type or P-type dopants, depends upon the type of transistor being made, i.e., an NFET transistor or a PFET transistor, respectively. Such implantation processes are performed using well-known ion implantation equipment. In such an example, the phrase “source/drain implant process” should be understood to cover one or both of the extension implant process and the source/drain implant process described above. Similarly, the phrase “source/drain implant region” should be understood to cover one or both of the extension implant regions and the highly doped source drain regions described above. In some applications, the source/drain regions for a transistor device may be formed by performing only a single implant process that forms a single implant region, and the specific phrases identified above should also be understood to cover such a single implant process—single implant region situation.

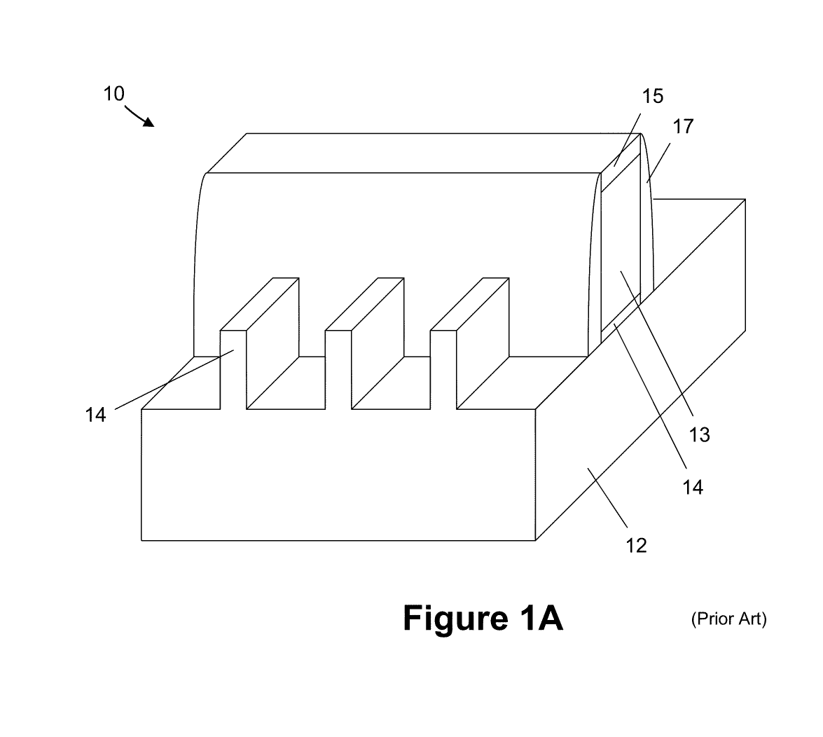

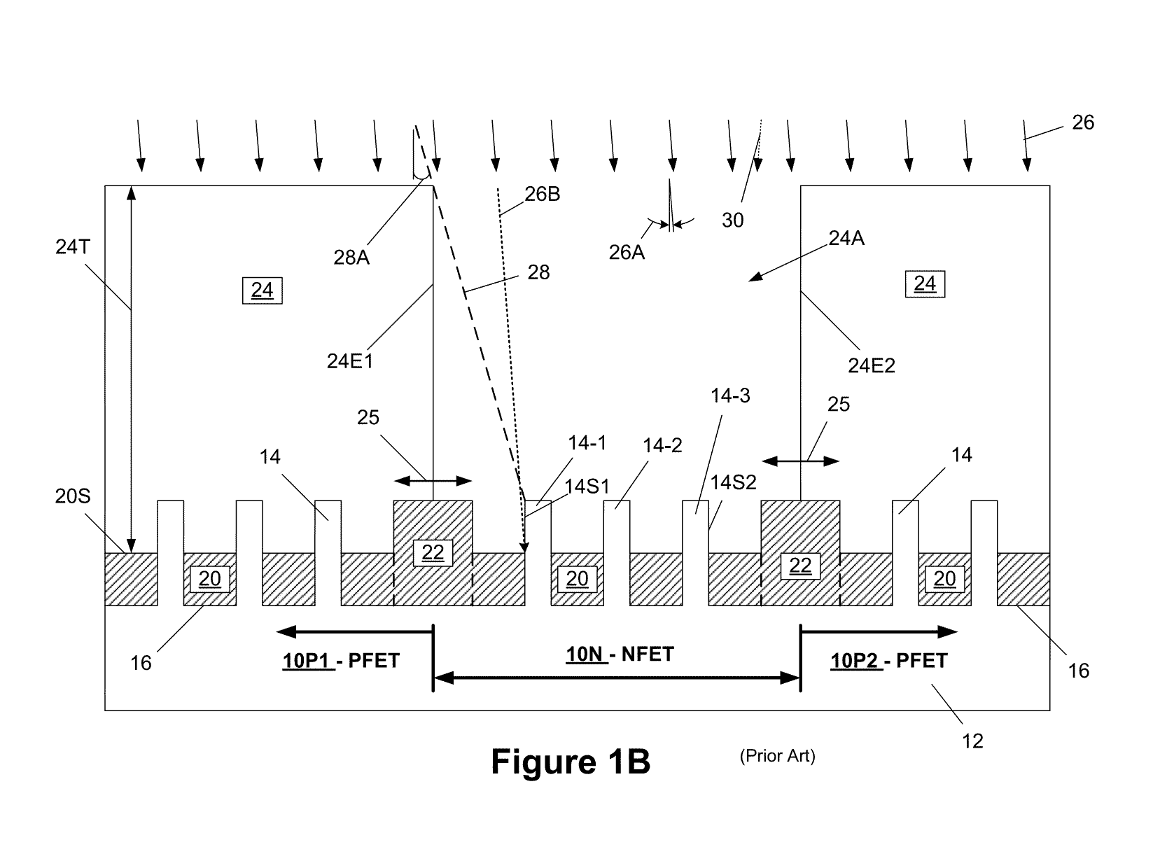

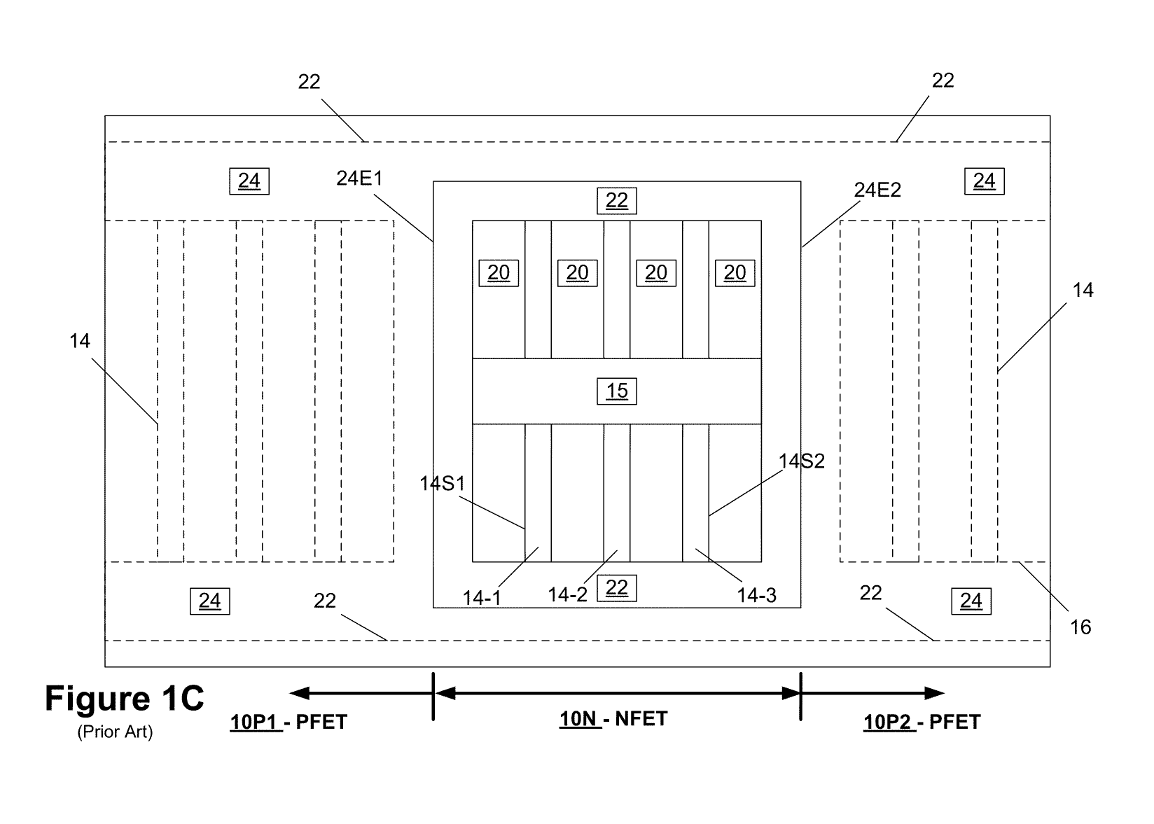

The inventions described herein will be disclosed in the context of making illustrative FinFET devices. However, as will be appreciated by those skilled in the art after a complete reading of the present application, the methods disclosed herein may be employed with other types of 3-D devices, such as shallow trench devices. Thus, the inventions disclosed herein should not be considered to be limited to any particular type or form of semiconductor device. To the extent that the drawings discussed below include the same reference numbers as used in FIGS. 1A-1C, the discussion regarding those common features applies equally to the drawing discussed below.

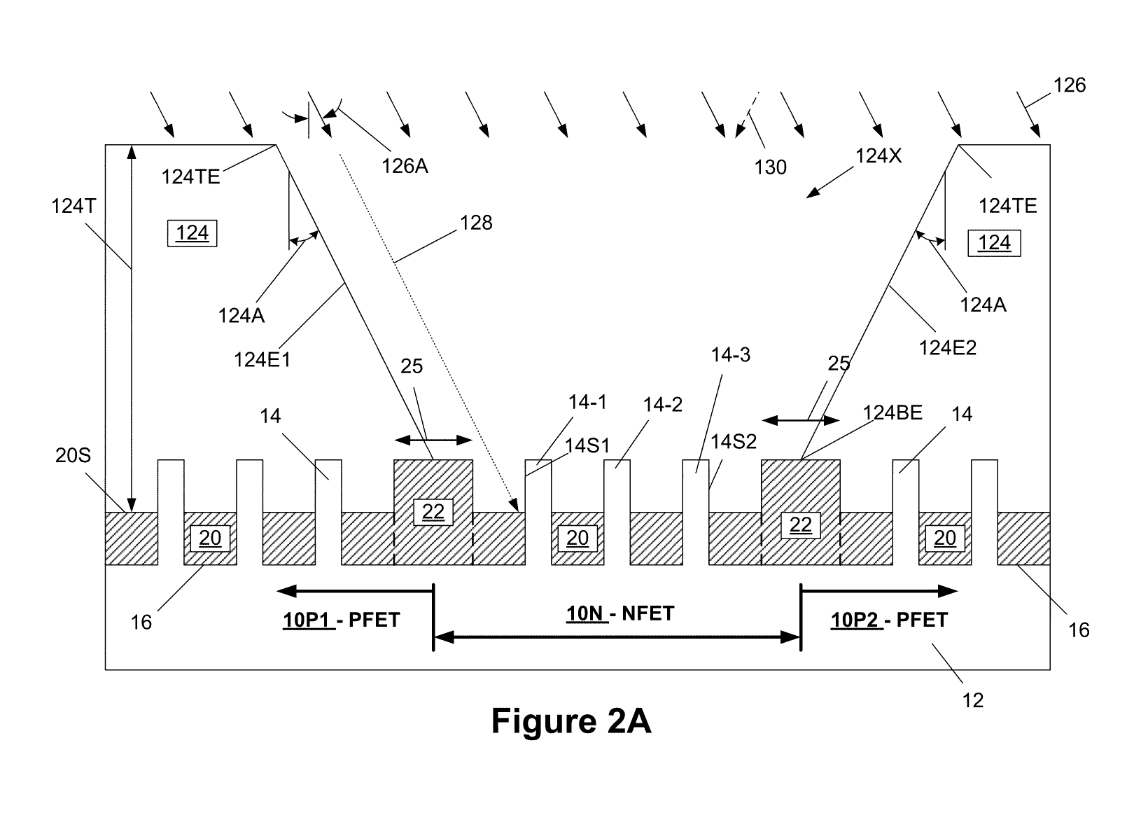

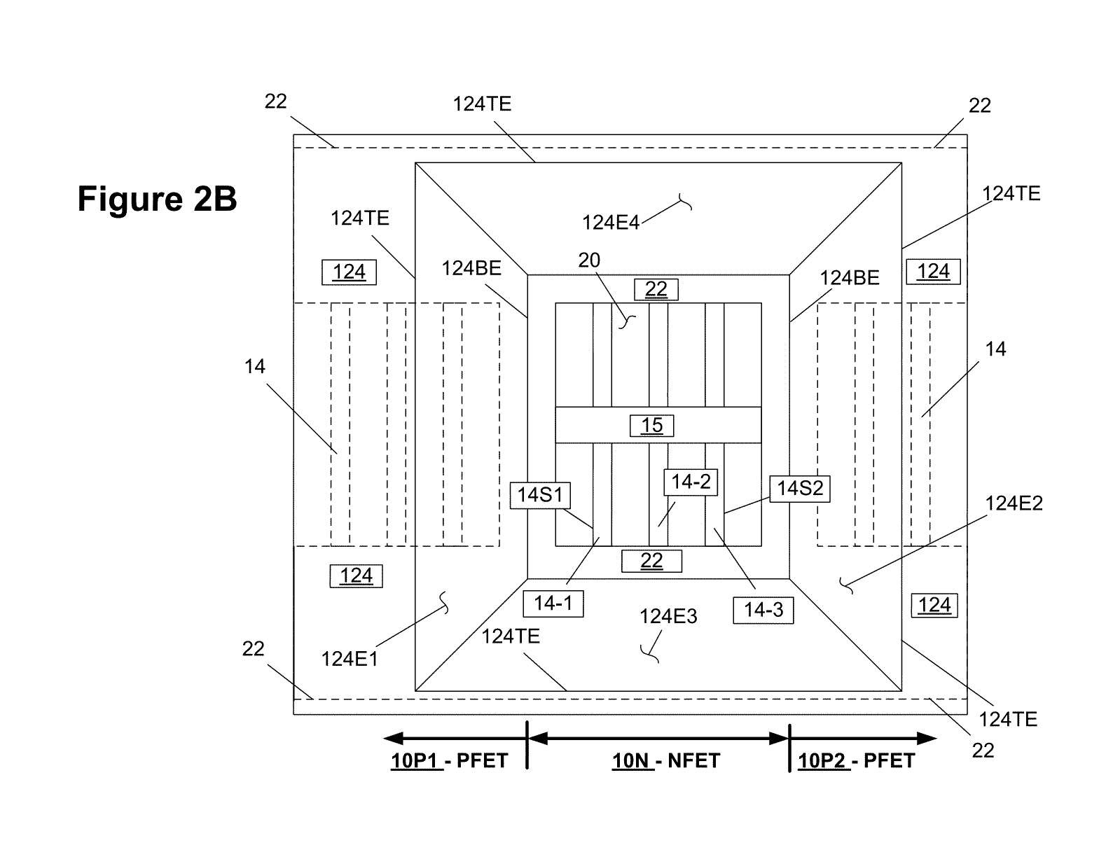

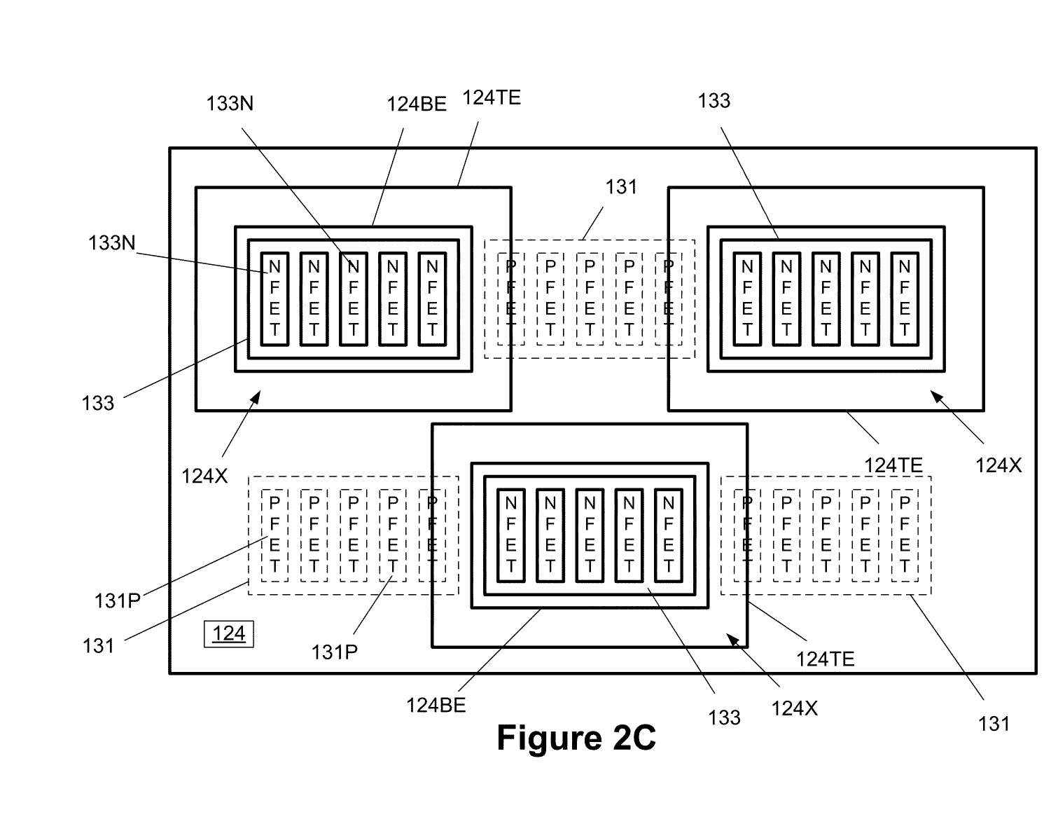

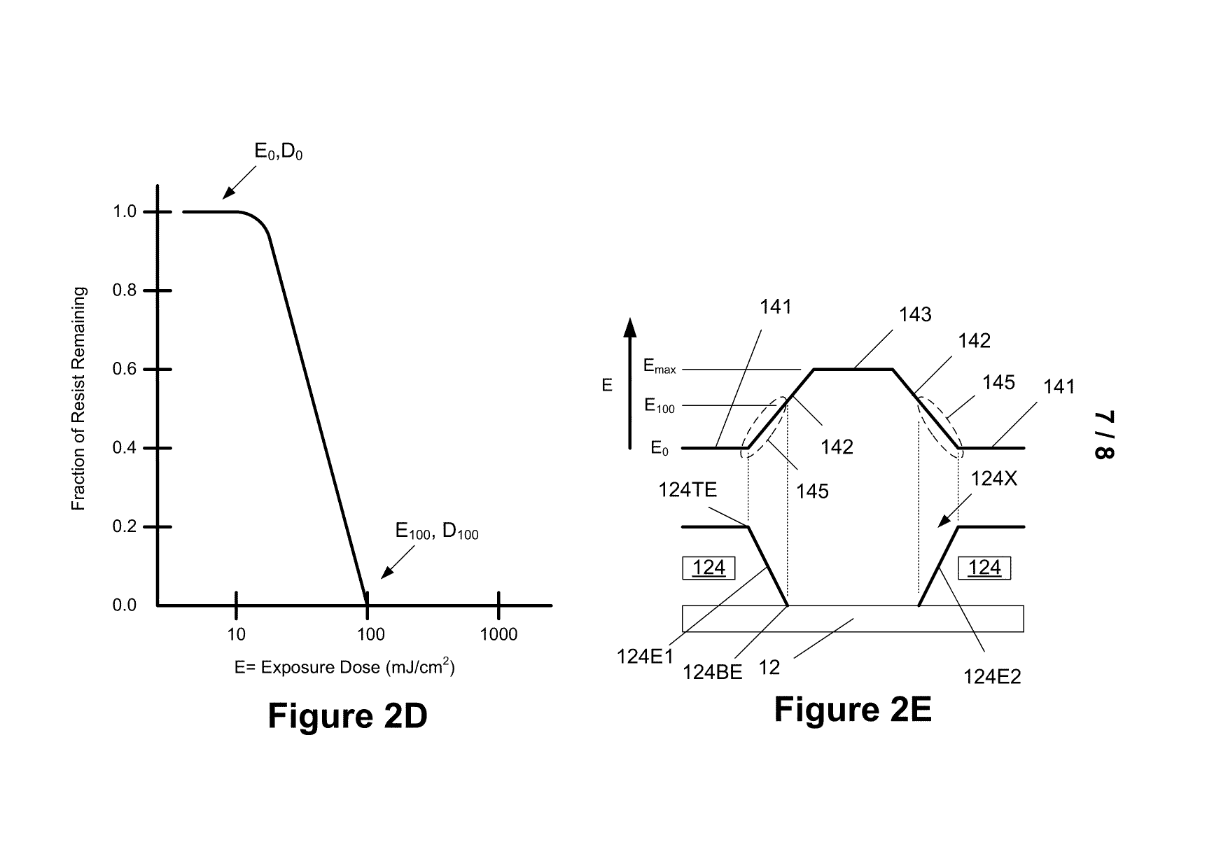

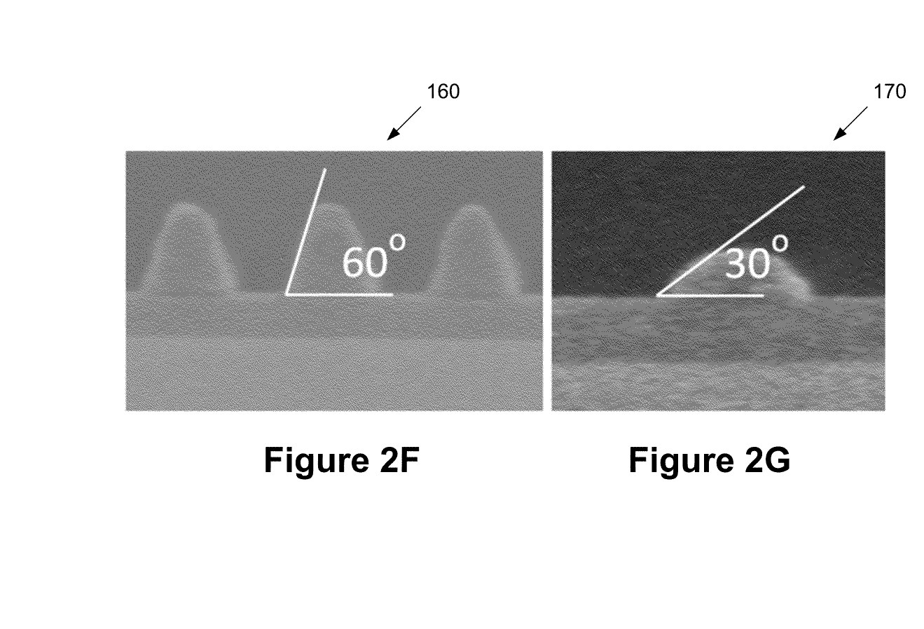

FIG. 2A is a cross-sectional view of one illustrative embodiment of an integrated circuit product comprised of the N-FinFET device 10N positioned between the two P-FinFET devices 10P1, 10P2. FIGS. 2B and 2C are plan views of one illustrative embodiment of an integrated circuit product comprised of N-FinFET devices and P-FinFET devices. The products are formed above the semiconducting substrate 12. The substrate 12 may have a variety of configurations, such as the depicted bulk silicon configuration. The substrate 12 may also have a silicon-on-insulator (SOI) configuration that includes a bulk silicon layer, a buried insulation layer and an active layer, wherein semiconductor devices are formed in and above the active layer. Thus, the terms “substrate” or “semiconducting substrate” should be understood to cover all forms of semiconductor structures. The substrate 12 may also be made of materials other than silicon.

The integrated circuit product shown in FIGS. 2A-2C is depicted at the point in fabrication where trenches 16 have been formed in the substrate 12 to thereby define the fins 14. Local isolation regions 20 and device isolation regions 22 have been formed using traditional manufacturing techniques well known to those skilled in the art.

At the point of fabrication depicted in FIGS. 2A-2B, a novel patterned photoresist implant mask 124 has been formed above the substrate 12 prior to performing one or more ion implantation processes to form source/drain regions (not shown) on the N-FinFET device 10N. The patterned photoresist implant mask 124 covers the two P-FinFET devices 10P1, 10P2 and exposes the N-FinFET device 10N for further processing. The patterned photoresist implant mask 124 may be formed using traditional photolithography equipment and techniques, and it may be made of either a positive or negative photoresist material. The thickness or height 124T of the patterned photoresist implant mask 124 may vary depending upon the particular application and a variety of factors, such as the implant energy to be used during the source/drain implant process(es). For example, the thickness or height 124T of the patterned photoresist implant mask 124 may range from about 100 nm to 0.5 μm or greater.

Importantly, in contrast to the prior art patterned photoresist implant mask 24, using the novel methods disclosed herein, the patterned photoresist implant mask 124 is formed such that it has an opening 124X that is defined by a plurality of non-vertical sidewalls 124E1, 124E2, 124E3 and 124E4. See FIGS. 2A-2B. The opening 124X is wider at its top opening edge 124TE than it is at its bottom opening edge 124BE. In one illustrative embodiment, the non-vertical sidewalls 124E1, 124E2, 124E3, 124E4 may be generally sloped sidewalls that have a substantially linear or planar surface, wherein the sidewalls are oriented at an angle 124A of approximately 30-60° relative to the vertical.

As shown in FIG. 2A, a representative ion implant process 126 is performed on the device through the opening 124X in the patterned photoresist implant mask 124 for purposes of forming source/drain regions (not shown) in the fins 14 of the N-FinFET device 10N. The implant process 126 is representative in that, as noted above, the source/drain regions may be formed by performing one or more implant processes, e.g., by performing a so-called extension implant process followed by performing a so-called source/drain implant process. The dopant dose and implant energy used in the implant process 126 may vary depending upon the particular application. The implant process 126 cases ions, represented by the dashed line 128, to be directed toward the fins 14, as shown in FIG. 2A.

One advantage of using the novel patterned photoresist implant mask 124 disclosed herein is that it reduces the amount of shadowing by the patterned photoresist implant mask 124 when any angled implant process, such as the illustrative implant process 126, is performed to form source/drain implant regions on the fins 14. By virtue of the opening 124X being defined by at least the sidewalls 124E1, 124E2, the implant process 126 may be performed at a greater implant angle 126A. In one illustrative embodiment, the implant angle 126A may be about the same as or less than the implant angle 124A of the sidewalls 124E1, 124E2. Thus, the ions 128 generated during the implant process 126 will have full access to the complete vertical height of the sidewall 14S1 of the fin 14-1. By using the novel patterned photoresist implant mask 124 disclosed herein, the various ion implantation processes that are performed to form source/drain implant regions on the device 10N may be performed at a greater angle (relative to the vertical) than they could be performed when using the prior art patterned photoresist implant mask 24 that has substantially vertical sidewalls. By performing the implant process 126 at a large angle, problems such as damage to the fins 14, e.g., sputtering of the fin, may be reduced or avoided.

Of course, as will be appreciated by those skilled in the art, the ion implant processes 126 that are performed to form the source/drain regions for the N-FinFET device 10N shown in FIG. 2A are typically performed in multiple steps to avoid the shadowing effect of adjacent fins 14. For example, after the depicted implant process 126 is performed to form an implant region in the side 14S1 (and other corresponding sides of the fins 14-2 and 14-3), the device will be rotated 180°, and another angled implant process 130 will be performed to form implant regions in the side 14S2 of the fin 14-3 (and other corresponding sides of the fins 14-1 and 14-2).

FIG. 2C depicts an illustrative embodiment where NFET and PFET devices are grouped together. More specifically, FIG. 2C depicts a plurality of P-regions 131 where a plurality of P-type FinFET devices 131P are formed and a plurality of N-regions 133 where a plurality of P-type FinFET devices 133N is formed. In the depicted example, the novel patterned photoresist implant mask 124A has three openings 124X that expose the N-regions 133 while covering the P-regions 131. After the source/drain implant regions are formed on the N-type FinFET devices 133N, the depicted patterned photoresist implant mask 124 may be removed and another patterned photoresist implant mask 124 may be formed that covers the N-regions 133 but has a plurality of openings that expose the P-regions 131 so that source/drain implant regions may be formed on the P-type FinFET devices 131P.

A typical photolithography process generally involves the steps of: (1) applying a layer of photoresist above a wafer, typically accomplished by a spin-coating process; (2) pre-baking (or soft-baking) the layer of photoresist at a temperature of approximately 90-120° C. to reduce the level of solvents in the layer of photoresist and to improve the adhesion characteristics of the photoresist; (3) performing an exposure process, wherein a pattern on a reticle is projected onto the layer of photoresist used in a stepper tool to create a latent image in the layer of photoresist; (4) performing a post-exposure bake on the layer of photoresist at a temperature approximately 5-15° C. higher than the pre-bake process; (5) performing a develop process to turn the latent image in the layer of photoresist into the final resist image; and (6) performing a post-bake process (or hard-bake) at a temperature of approximately 125-160° C. to remove residual solids and to improve adhesion of the patterned photoresist mask. These process steps are well known to those skilled in the art and, thus, will not be described herein in any greater detail except as they are modified as described herein to form the novel patterned photoresist implant mask 124.

Photolithography tools and systems typically include a source of radiation at a desired wavelength, an optical system and, typically, the use of a so-called mask or reticle that contains a pattern that is desired to be formed on a wafer. Radiation is provided through or reflected off the mask or reticle to form an image on a semiconductor wafer. The radiation used in such systems can be light, such as ultraviolet light, deep ultraviolet light (DUV), vacuum ultraviolet light (VUV), extreme ultraviolet light (EUV), etc. The radiation can also be x-ray radiation, e-beam radiation, etc. Generally, the image on the reticle is utilized to irradiate the light-sensitive layer of photoresist material. Currently, most of the photolithography systems employed in semiconductor manufacturing operations are so-called deep ultraviolet systems (DUV) that generate radiation at a wavelength of 248 nm or 193 nm. However, the capabilities and limits of traditional DUV photolithography systems are being tested as device dimensions continue to shrink. This has led to the development of a so-called EUV system that uses radiation with a wavelength less than 20 nm, e.g., 13.5 nm.

FIG. 2D is a contrast curve of a photoresist material that is related to the exposure process that is typically performed on the photoresist material when making the patterned photoresist implant mask 124. More specifically, the horizontal axis is the irradiation energy or exposure dose used when performing the above-referenced exposure process on the photoresist material. The vertical axis is a plot of the fraction of the resist material that remains after it is fully developed, i.e., after the above-mentioned hard bake process has been performed on the photoresist material. All photoresist materials exhibit similar characteristics to those depicted in FIG. 2D. The point “E₁₀₀” or “D₁₀₀” reflects the irradiation energy level (“E₁₀₀”—in this case about 100 mJ/cm²) where the photoresist material will be removed totally after development. The point “E₀” or “D₀” reflects the irradiation energy level (“E₀”—in this case about 10 mJ/cm² and below) where none of the photoresist material will be removed after development, i.e., “E₀” or “D₀” reflects the situation where all of the original photoresist material remains in place.

FIG. 2E is a drawing that reflects the variations in exposure dose (E) of the exposure process to the resulting profile of the sidewalls 124E1-124E2 in the patterned photoresist implant mask 124. In the illustrative example depicted in FIG. 2E, the energy level of the irradiation process goes from an initial level E₀ (lines 141) at locations laterally outside of the top edge 124TE, through a transition region (lines 142), and ultimately ramps up to a maximum level Eₘₐₓ (line 143). At the point where the energy begins to increase from level E₀, i.e., the portion of the photoresist material that will correspond to the top edge 124TE, the patterned photoresist implant mask 124 is irradiated with an energy level that will allow a very small amount of the photoresist material to be removed. At the locations where the exposure dose of the exposure process equals E₁₀₀ or greater, all of the exposed photoresist material will be removed. Thus, as shown in FIG. 2E, the location where the exposure dose E₁₀₀ is reached will correspond to the bottom edge 124BE of the opening 124X. Of course, all of the photoresist material that is exposed to energy levels above E100 will be subsequently removed in the photoresist develop process discussed above. Accordingly, the areas of the photoresist material that are irradiated with the energy levels depicted in the dashed regions 145, will produce, when fully developed and processed, the patterned photoresist implant mask 124 comprised of the non-vertical sidewalls 124E1, 124E2, 124E3 and 124E described above.

In general, photolithography involves the use of a so-called photo mask that contains the image desired to be transferred to a layer of photoresist. A photo mask is generally comprised of a transparent glass material and a patterned layer of chrome formed on the glass material. The photo mask thus contains transparent regions (glass only) and non-transparent regions (the portions of the glass covered by the patterned layer of chrome). At the edge of patterns in a photo mask, light transmission through the photo mask changes from 100% in the transparent area, to 0% in the not-transparent regions, i.e., the chrome covered regions. This means that intensity of the irradiating light during the exposure process in this transition region changes from zero to a maximum value across the edge of the pattern in the layer of photoresist material 124 (141 (energy=0) to 143 (energy=max) in FIG. 2E). This variation in the intensity of the irradiating light in the transition region (from transparent to non-transparent) causes the sidewalls or edges 124E1-124E4 of the opening 124X to receive different levels of exposure. As a result, after development, the thickness of the layer of photoresist 124 continuously changes from a maximum thickness (the original thickness) at the top edge 124TE (energy=Eₒ) to zero thickness at the bottom edge 124BE (energy=E₁₀₀), as indicated in FIG. 2E. The slope of the sidewalls 124E1-124E4 will vary depending upon the steepness of the contrast curve of the photoresist material, i.e., using a photoresist material with a more steeply sloped contrast curve will result in the sidewalls 124E1-E4 having a steeper slope. By selecting a photoresist material with a right contrast curve, the angle 124A (see FIG. 2A) of the sloped sidewalls 124E1-124E4 can be adjusted to a desired range, e.g., an angle of about 30-60 degrees. The desired resist profile can be obtained by using a photoresist material with high absorption and high resist loss. These types of high absorption/high loss photoresist materials are commonly seen in the early development phase when developing a photoresist material. FIGS. 2F and 2G are images of cross-sectioned patterned photoresist layers 160, 170, respectively, where the photoresist material is early KrF resists (EXP X 25-2225A and EXP X 25-2225B, respectively). The formulation of the photoresist materials may be adjusted to realize a profile angle of about 60 degrees relative to a horizontal surface for the layer 160 (FIG. 2F) or 30 degrees relative to a horizontal surface for the layer 170 (FIG. 2G). In this example, the photoresist material used for the layer 170 has a higher absorption rate than the photoresist material used for the layer 160. Thus, the features in the patterned photoresist layer 170 (FIG. 2G) exhibit more loss of resist material and have a smaller profile angle (30°) as compared to the features in the patterned photoresist layer 160 (FIG. 2F) which have a larger profile angle)(60°).

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method of forming source/drain implant regions on a device comprising an N-type FinFET device and a P-Type FinFET device, each or which are comprised of at least one fin, wherein the method, comprises:
forming a patterned photoresist implant mask above said device, wherein said patterned photoresist implant mask has an opening that is defined, at least partially, by a plurality of non-vertical sidewalls, and wherein said patterned photoresist implant mask covers one of said N-type FinFET or P-type FinFET device, while the other of said N-type FinFET or P-type FinFET device is exposed by said opening in said patterned photoresist implant mask; and
performing at least one source/drain implant process through the opening in said patterned photoresist implant mask to form a doped source/drain implant region in said at least one fin of said other of said N-type FinFET or P-type FinFET device exposed by said opening in said patterned photoresist implant mask.

2. The method of claim 1, wherein performing said at least one source/drain implant process to form said doped source/drain implant region comprises performing a single ion implantation process.

3. The method of claim 1, wherein performing said at least one source/drain implant process to form said doped source/drain implant region comprises performing multiple ion implantation processes.

4. The method of claim 1, wherein performing said at least one source/drain implant process to form said doped source/drain implant region comprises:
performing a first extension ion implantation process to form extension implant regions in said at least one fin; and
performing a second source/drain ion implantation process to form highly doped source/drain implant regions in said at least one fin.

5. The method of claim 1, wherein said plurality of non-vertical sidewalls are sloped sidewalls that are formed at an angle, with respect to a vertical, within the range of about 30-60 degrees.

6. The method of claim 1, wherein said plurality of non-vertical sidewalls is comprised of four non-vertical sidewalls.

7. A method of forming source/drain implant regions on a device comprising an N-type FinFET device and a P-Type FinFET device, each or which are comprised of at least one fin, wherein the method, comprises:
forming a patterned photoresist implant mask above said device, wherein said patterned photoresist implant mask has an opening that is defined, at least partially, by a plurality of sloped sidewalls that are formed at an angle, with respect to a vertical, within the range of about 30-60 degrees, and wherein said implant mask covers one of said N-type FinFET or P-type FinFET device, while the other of said N-type FinFET or P-type FinFET device is exposed by said opening in said patterned photoresist implant mask; and
performing multiple source/drain implant processes through the opening in the patterned photoresist implant mask to form a doped source/drain implant region in said at least one fin of said other of said N-type FinFET or P-type FinFET device exposed by said opening in said patterned photoresist implant mask.

8. The method of claim 7, wherein performing said multiple source/drain implant processes to form said doped source/drain implant region comprises:
performing a first extension ion implantation process to form extension implant regions in said at least one fin; and
performing a second source/drain ion implantation process to form highly doped source/drain implant regions in said at least one fin.

9. The method of claim 7, wherein said plurality of sloped sidewalls is comprised of four sloped sidewalls.

10. A method of forming a patterned photoresist implant mask that has an opening that is defined, at least partially, by a plurality of sloped sidewalls that are formed at an angle, with respect to a vertical, within the range of about 30-60 degrees on a device comprising an N-type FinFET device and a P-Type FinFET device, each or which are comprised of at least one fin, wherein the method, comprises:
selecting a photoresist material that has a contrast curve that is adapted to, after exposure and development, produce said patterned photoresist implant mask with said opening comprised of said plurality of sloped sidewalls that are formed at an angle, with respect to a vertical, within the range of about 30-60 degrees;
forming a layer of said selected photoresist material above said device;
performing at least exposure and development processes on said selected layer of photoresist material to thereby form said patterned photoresist implant mask with said plurality of sloped sidewalls that are formed at said angle within the range of about 30-60 degrees, and wherein said patterned photoresist implant mask covers one of said N-type FinFET or P-type FinFET device, while the other of said N-type FinFET or P-type FinFET device is exposed by said opening in said patterned photoresist implant mask; and
performing at least one source/drain implant process through the opening in the patterned photoresist implant mask to form a doped source/drain implant region in said at least one fin of said other of said N-type FinFET or P-type FinFET device exposed by said opening in said patterned photoresist implant mask.

11. The method of claim 10, wherein performing said at least one source/drain implant process to form said doped source/drain implant region comprises performing multiple ion implantation processes.

12. The method of claim 10, wherein performing said at least one source/drain implant process to form said doped source/drain implant region comprises:
performing a first extension ion implantation process to form extension implant regions in said at least one fin; and
performing a second source/drain ion implantation process to form highly doped source/drain implant regions in said at least one fin.

13. The method of claim 10, wherein said plurality of sloped sidewalls is comprised of four sloped sidewalls.
